(19) United States
(12) Patent Application Publication
(10) Pub. No.: US 2013/0153746 A1
(43) Pub. Date: Jun. 20, 2013

(54) OPTICAL SCANNING DEVICE, LIGHT INTENSITY ADJUSTMENT METHOD THEREOF, AND COMPUTER PROGRAM PRODUCT

(71) Applicants: Takao WATANABE, Kanagawa (JP); Shinji KOBAYASHI, Tokyo (JP); Hiroaki KYOGOKU, Hyogo (JP)

(72) Inventors: Takao WATANABE, Kanagawa (JP); Shinji KOBAYASHI, Tokyo (JP); Hiroaki KYOGOKU, Hyogo (JP)

(21) Appl. No.: 13/721,536

(22) Filed: Dec. 20, 2012

(30) Foreign Application Priority Data
Dec. 20, 2011 (JP) 2011-278223
Dec. 12, 2012 (JP) 2012-271549

(51) Int. Cl. H01L 31/14

(52) U.S. Cl. CPC H01L 31/14
USPC 250/205

(57) ABSTRACT

An optical scanning device includes a light source; a light source driving unit that drives the light source; a detecting unit that detects light intensity emitted from the light source; a light intensity adjustment determining unit that determines whether or not it is necessary to adjust the light intensity emitted from the light source; a detected-light-intensity determining unit that determines whether or not the light intensity detected by the light intensity detecting unit is at a predetermined light intensity; and a light intensity adjusting unit that, when it is determined that the light intensity needs to be adjusted, amplifies the light intensity emitted from the light source with an amplification factor that is set according to the imaging condition to adjust a driving current of the light source driving unit and to thereby adjust the light intensity, which is determined by the detected-light-intensity determining unit, to the predetermined light intensity.

### CROSS-REFERENCE TO RELATED APPLICATIONS

The present application claims priority to and incorporates by reference the entire contents of Japanese Patent Application No. 2011-278223 filed in Japan on Dec. 20, 2011 and Japanese Patent Application No. 2012-271549 filed in Japan on Dec. 12, 2012.

### BACKGROUND OF THE INVENTION

1. Field of the Invention

The present invention relates to a light scanning device that is used in a laser printer, a digital copying machine, a plain paper facsimile apparatus, or the like; as well as relates to and a light intensity adjustment method of the optical scanning device and a computer program product.

2. Description of the Related Art

FIG. 6 is an explanatory diagram illustrating an example of an optical scanning device that is disposed in a conventional image forming apparatus and in which a photosensitive member is scanned with a laser beam. An optical scanning device 1 includes a laser diode (LD) unit 10, a polygon mirror (rotary polygon mirror) 12, an imaging lens (f-θ lens) 14, a photosensitive member 16, a beam sensor 18, a laser driving device 20, and an optical writing control unit 22. The LD unit 10 has a built-in LD 101 and a built-in light receiving element 102. The beam sensor 18 is disposed at the end in the main-scanning direction of optical beams. The beam sensor 18 receives an optical beam, generates a main-scanning synchronization signal, and inputs the main-scanning synchronization signal to the optical writing control unit 22. Then, in synchronization with the main-scanning synchronization signal, the optical writing control unit 22 sends image data and an APC timing signal (APC stands for Automatic Power Control) to the laser driving device 20. Based on the image data and the APC timing signal, the laser driving device 20 instructs the LD 101 of the LD unit 10 to emit an optical beam (a scanning beam).

As illustrated in FIG. 6, the optical beam emitted by the LD 101 gets rotary-scanned by the polygon mirror 12. Then, main-scanning on the photosensitive member 16 is performed by means of uniform velocity scanning through the imaging lens 14. At that time, the photosensitive member 16 is rotated in the sub-scanning direction. As a result, a two-dimensional electrostatic latent image is formed on the photosensitive member 16. Then, a developing unit (not illustrated) develops the electrostatic latent image using a toner. That results in the formation of a toner image. Subsequently, a transfer unit (not illustrated) transfers the toner image onto a paper sheet; and a fixing unit (not illustrated) applies a certain pressure while melting the toner so that the toner image gets fixed to the paper sheet. That results in the formation of a printed image.

Meanwhile, in order to form an electrostatic latent image on the photosensitive member 16, it is necessary to have a predetermined light intensity that matches with the sensitivity characteristic of the photosensitive member 16. Regarding the light intensity adjustment of the LD 101 that is the laser light source of the optical scanning device 1, the light received by the light receiving element 102, which is embedded in the LD unit 10, is subjected to photoelectric conversion; the current (monitor current) that is obtained by means of photoelectric conversion is converted into voltage using an external volume resistance; the voltage obtained by means of current-to-voltage conversion is input to a comparator; a comparison between the voltage and a reference voltage is performed in the comparator; and control is performed accordingly using APC. In this case, the light intensity adjustment is performed by rotating the volume resistance (i.e., by changing the resistance value) by changing the driving current of the LD so as to increase or decrease the light emitting power of the LD and by maintaining the volume resistance value obtained at the point of time when a predetermined light intensity is achieved.

FIG. 7 is a circuit diagram illustrating a configuration of a conventional LD light intensity adjustment device that is configured with an LD drive circuit 200, which is embedded in the laser driving device 20, and the LD unit 10. The LD light intensity adjustment device includes the LD drive circuit 200; an external volume resistance 205; and the light receiving element (PIN photodiode (hereinafter, referred to as “PD”)) 102 that functions as a light intensity detecting unit and, of the laser light emitted from LDs 101a and 101b serving as light sources, detects light on the back beam side of an LD reflection end face. The LD drive circuit 200 includes reference voltage DACs 201a and 201b (DAC stands for digital-to-analog converter); comparators (CPs) 202a and 202b; driving current DACs 203a and 203b; and a switching unit S such as a switch for switching the monitor output voltage of the PD 102 to one of the comparators 202a and 202b.

In this LD light intensity adjustment device, when the LD 101a or the LD 101b is made to emit light; the PD 102 embedded in the LD unit 10 detects, inside the LD unit 10, the light on the back beam side of the LD reflection end face and accordingly outputs a monitor current. Then, the volume resistance 205 performs current-to-voltage conversion with respect to the monitor current and outputs a monitor voltage to the LD drive circuit 200. Subsequently, depending on the switching performed by the switching unit S, the monitor voltage is compared with an output reference voltage Vs of either the reference voltage DAC 201a or the reference voltage DAC 201b of the LD drive circuit 200. The comparison result is input either to the driving current DAC 203a or the driving current DAC 203b. Then, the volume resistance 205 is so adjusted that, based on the comparison result, the driving current DAC 203a or the driving current DAC 203b increases or decreases the driving current to the LD 101a or the LD 101b, respectively, and alters the light intensity of that LD. Once the volume resistance value is fixed to a value at which a predetermined (or an appropriate) light intensity is obtained; feedback control is performed thereafter for automatically maintaining that particular light intensity.

Meanwhile, there are times when the rest energy for laser exposure that is required to form an electrostatic latent image on the photosensitive member 16 differs depending on imaging conditions such as the sub-scanning speed of the photosensitive member 16, the writing speed of formed images, and the number of rotations of the polygon mirror 12. In such a case, it becomes necessary to change the light intensity of the LDs 101a and 101b for each imaging condition. In a conventional LD light intensity adjustment device, the LD light intensity can be altered by adjusting the volume resistance 205 in the above-mentioned manner, and accordingly the light intensity of the LDs 101a and 101b can be adjusted to a predetermined light intensity in concert with the imaging conditions. However, in an optical scanning device, consider a case when imaging conditions, such as the linear velocity of the photosensitive member, undergo a change; and the required light intensity also changes for each imaging condition. In such a case, if adjustment is performed using the volume resistance 205, only a single adjustment value can be held for a single resistance. Hence, light intensity adjustment cannot be performed according to a plurality of adjustment specifications for light intensity.

There, in the case of performing different light intensity adjustments according to different imaging conditions; in the conventional LD light intensity adjustment device, the reference voltage DAC 201a or the reference voltage DAC 201b is changed and a new adjustment value is set. However, if the reference voltage DAC 201a or the reference voltage DAC 201b is changed, then the linearity error of the reference voltage DAC 201a or the reference voltage DAC 201b, or the linearity error of the driving current DAC 203a or the driving current DAC 203b gets included by necessity. Besides, the output characteristics of the monitor current with respect to the LD light intensity are controlled on the assumption that linearity is almost secured. Hence, in a conventional LD light intensity adjustment device, in the case of performing control with a light intensity that is different than the light intensity with which light intensity adjustment was previously performed, there occurs a light intensity error of several percent.

For example, once the LD light intensity has been adjusted, if the light intensity is to be exactly halved, then it is ought to be sufficient to halve the values of the driving current DACs (i.e., halve the driving current values). However, because of the linearity error of the monitor current and the light intensity or because of the linearity error of the driving current DACs; the LD light intensity is not exactly halved in actuality, and there occurs a light intensity error of about several percent as described above.

Besides, in the first place, the scope of control for controlling reference voltage DACs is restricted by the setting of the DAC dynamic range. In the case of performing light intensity control using reference voltage DACs; a greater scope of light intensity control needs to be secured because, apart from performing correction of the rest energy for laser exposure that is different according to the imaging conditions, a light intensity correction control is also performed for correcting the variation in the imaging conditions that is caused by device operations and a shading correction control is also performed for correcting the exposure energy unevenness that is caused by the optical characteristic of the scanning optical system (i.e., the shading characteristic of the scanning optical system). However, if a greater scope is secured for light intensity control performed using reference voltage DACs, then the light intensity control resolution per bit (per digit) of the reference voltage DACs becomes coarse. Thus, in order to achieve a fine light intensity control resolution while securing a greater scope of control, it becomes necessary to increase the bit count of the reference voltage DACs. That leads to an increase in the circuit size.

In order to resolve such issues and eliminate the errors; it is thinkable to provide external volume resistances that are equal in number to the number of light control specifications resulting from the differences in imaging conditions, and to use an analog switch for switching between the volume resistances to be connected to a PD for each imaging condition. With that, it becomes possible to perform the most suitable light intensity adjustment for each imaging condition.

FIG. 8 is a diagram illustrating a circuit configuration of that LD light intensity adjustment device. Herein, to the configuration of the LD light intensity adjustment device illustrated in FIG. 7, a light intensity switching circuit 204 and a plurality of (herein, three) volume resistances 205 (205a, 205b, and 205c) are additionally disposed. The switching of the volume resistances 205 is performed using the light intensity switching circuit 204.

In this LD light intensity adjustment device, a plurality of adjustment values can be held using the volume resistances 205a, 205b, and 205c. As a result, it becomes possible to perform an error-free and most suitable light intensity adjustment for each different imaging condition. Moreover, it also becomes possible to resolve the issues that arise from increasing the scope of light intensity control, which is performed by the reference voltage DACs as described above.

However, in this LD light intensity adjustment device, it is a cumbersome task to manually adjust the light intensity by adjusting the volume resistances 205a, 205b, and 205c. Moreover, the addition of the volume resistances 205 (205a, 205b, and 205c) as well as the light intensity switching circuit 204 results in an increase in the manufacturing cost of the light intensity adjustment device. Hence, this configuration is not implementable under normal conditions.

In Japanese Patent Application Laid-open No. 2011-098494, an optical scanning device and an image forming apparatus are disclosed in which a monitor current is used in performing feedback control of the driving currents of LDs; the gain of feedback control is stored in a memory; and readjustment is performed if there is malfunctioning in the post-adjustment operations. The configuration of this optical scanning device is such that the volume resistances are decreased in number and the gain of feedback control is held in a memory. That is a point of similarity to the present invention described below. However, in that optical scanning device, if a different LD light intensity is used that is different from the adjustment point used previously for light intensity adjustment; then there is no resolution to the issue that an LD light intensity error occurs due to the linearity error of the monitor current and the light intensity, or due to the linearity error of the driving current DACs.

Therefore, there is a need for a light scanning device and a light intensity adjustment method thereof capable of performing a highly-accurate and error-free light intensity adjustment in a case of changing to a light intensity that is different than the light intensity which has been previously adjusted depending on the imaging conditions of an image forming apparatus and which has been output by the optical writing light source during light intensity adjustment of an optical writing light source.

### SUMMARY OF THE INVENTION

According to an embodiment, there is provided an optical scanning device that includes a light source; a light source driving unit that drives the light source; a light intensity detecting unit that detects light intensity emitted from the light source; a light intensity adjustment determining unit, a detected-light-intensity determining unit, and a light intensity adjusting unit. The light intensity adjustment determining unit determines, based on the presence or absence of a change in a predetermined imaging condition, whether or not it is necessary to adjust the light intensity emitted from the light source. The detected-light-intensity determining unit determines whether or not the light intensity emitted from the light source detected by the light intensity detecting unit is at a predetermined light intensity. When the light intensity adjustment determining unit determines that the light intensity emitted from the light source needs to be adjusted, the light intensity adjusting unit amplifies the light intensity emitted from the light source with an amplification factor that is set according to the imaging condition to adjust a driving current of the light source driving unit and to thereby adjust the light intensity emitted from the light source, which is determined by the detected-light-intensity determining unit, to the predetermined light intensity.

The above and other objects, features, advantages and technical and industrial significance of this invention will be better understood by reading the following detailed description of presently preferred embodiments of the invention, when considered in connection with the accompanying drawings.

### BRIEF DESCRIPTION OF THE DRAWINGS

FIG. 1 is a block diagram illustrating a circuit configuration and a functional configuration of a laser diode (LD) light intensity adjustment device that is used in an optical scanning device according to a first embodiment of the present invention;

FIG. 2 is a flowchart for explaining an example of LD light intensity adjustment performed according to the first embodiment;

FIG. 3 is a block diagram illustrating a circuit configuration and a functional configuration of an LD light intensity adjustment device that is used in an optical scanning device according to a second embodiment of the present invention;

FIG. 4 is an explanatory diagram of an example in which a gain value is set for each imaging condition;

FIG. 5 is a flowchart for explaining an example of LD light intensity adjustment performed according to the second embodiment;

FIG. 6 is an explanatory diagram illustrating an example of an optical scanning device that is disposed in a conventional image forming apparatus and in which a photosensitive member is scanned with a laser beam;

FIG. 7 is a circuit diagram illustrating a configuration of a conventional LD light intensity adjustment device that is configured with an LD drive circuit, which is embedded in a laser driving device, and an LD unit; and

FIG. 8 is a diagram illustrating a circuit configuration of another conventional LD light intensity adjustment device.

### DETAILED DESCRIPTION OF THE PREFERRED EMBODIMENTS

Exemplary embodiments of an optical scanning device, a light intensity adjustment method of the optical scanning device, and a computer program product according to the present invention are described in detail below with reference to the accompanying drawings.

Prior to the explanation regarding the embodiments, firstly, a rundown of the features of the optical scanning device is given. In a conventional optical scanning device described above, the current output of the PD 102, which is a light intensity detecting unit (a light receiving element) embedded in an LD unit, is subjected to current-to-voltage conversion using a volume resistance; and the volume resistance is altered with the aim of performing light intensity adjustment. Regarding the adjustment of a volume resistance; typically, a person manually rotates the volume resistance so as to achieve a predetermined light intensity. In that regard, as described earlier, the embodiments are given with the aim of achieving a highly-accurate light intensity adjustment as well as making an improvement in the conventional LD light intensity adjustment device in which light intensity adjustment is a cumbersome task. More particularly, the constituent element that corresponds to a volume resistance is turned into a digitized circuit so as to eliminate the manual operations required in the past, and the volume resistance value is replaced with the amplification factor of an amplifier circuit that amplifies the monitor current of an LD light intensity adjustment device. Such a configuration makes it possible to achieve automation of light intensity adjustment. Meanwhile, in the explanation of the embodiments, a laser diode is used as an optical writing light source, and is abbreviated as LD.

### First Embodiment

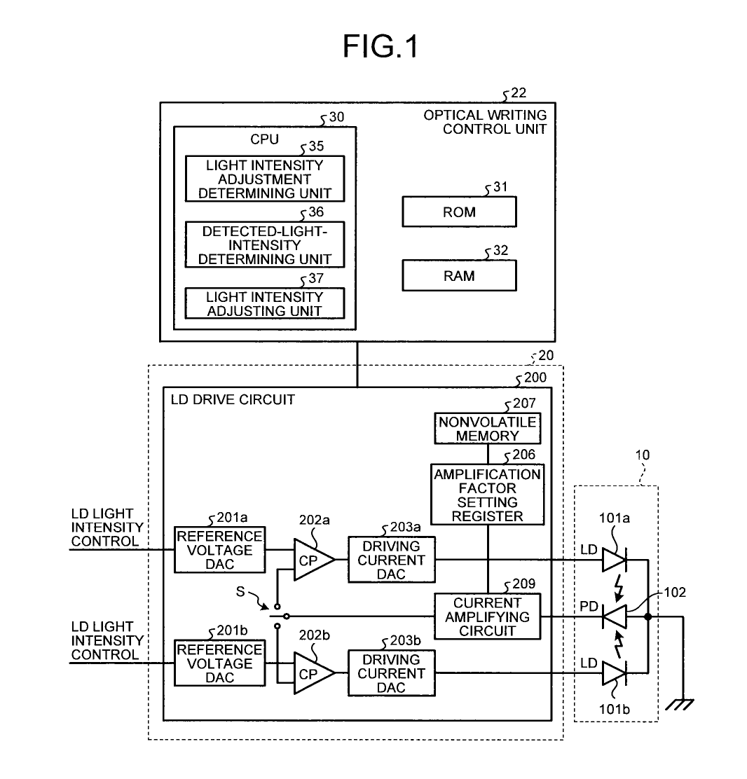

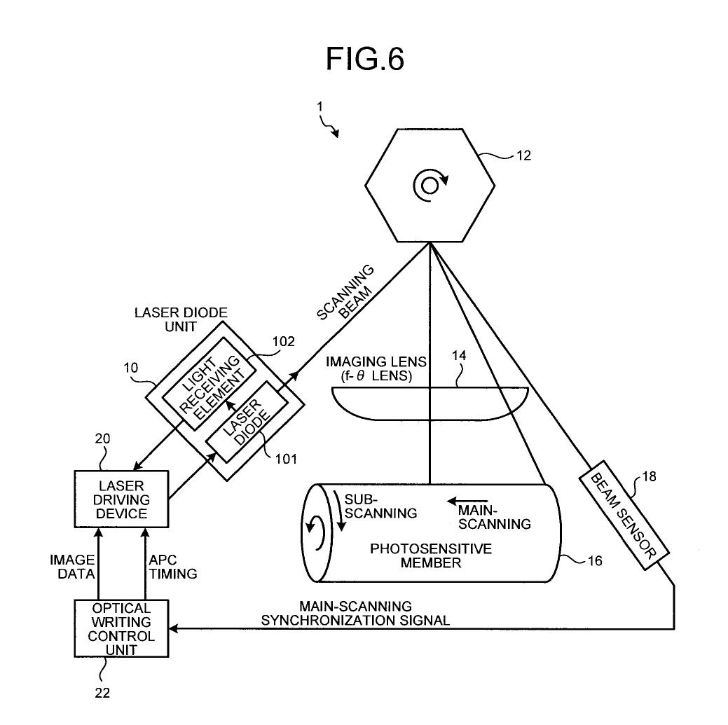

FIG. 1 is a block diagram illustrating a circuit configuration and a functional configuration of an LD light intensity adjustment device that is used in an optical scanning device according to a first embodiment. Herein, the structure of the optical scanning device according to the first embodiment is essentially the same to the conventional structure illustrated in FIG. 6. Hence, the following explanation is given under the assumption that the optical scanning device according to the first embodiment has the same structure as the conventional structure illustrated in FIG. 6.

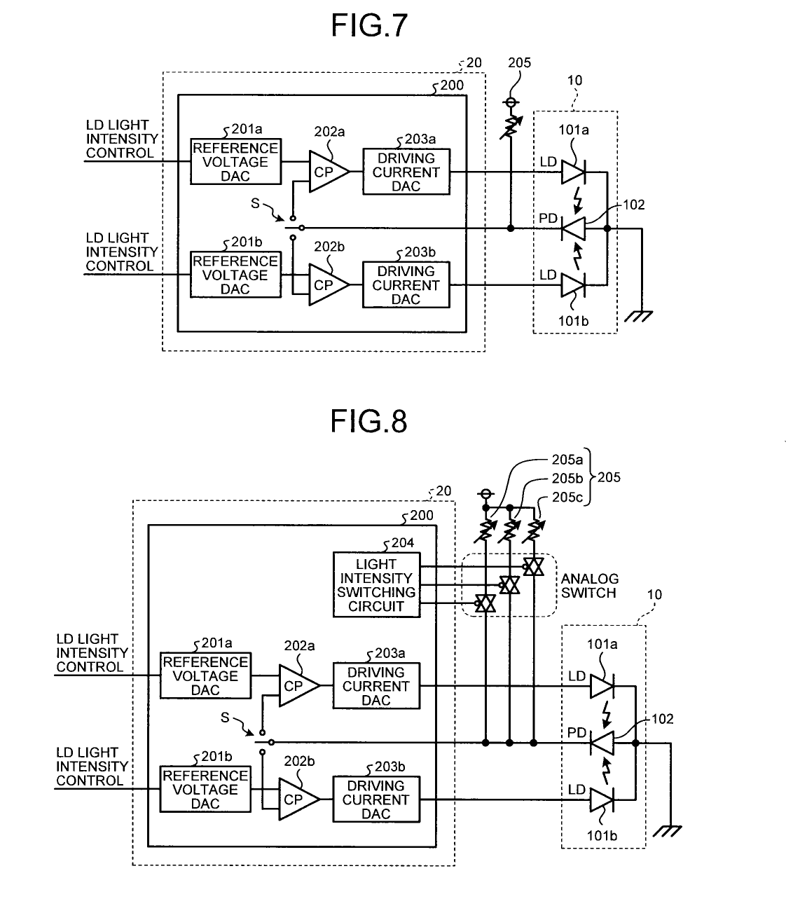

The LD light intensity adjustment device is essentially the same as the conventional LD light intensity adjustment device illustrated in FIG. 7. However, the volume resistance 205 is replaced with a current amplifying circuit 209 that is an amplifying unit for amplifying the monitor current of the PD 102 at an input unit of the LD drive circuit 200. The current amplifying circuit 209 amplifies the monitor current from the PD 102 and outputs it as a voltage value (monitor voltage value). Moreover, the gain value of the current amplifying circuit 209 is the gain value at which the desired amplification factor is achieved. The current amplifying circuit 209 calculates the amplification factor from the gain value. Moreover, an amplification factor setting register 206 is disposed that is a gain value setting/storing device used in setting a gain value; and a nonvolatile memory 207 is disposed that is used to store the gain value at the time when a predetermined light intensity is obtained during the light intensity adjustment of the LD performed using the LD light intensity adjustment device according to the first embodiment. Apart from that, the LD light intensity adjustment device according to the first embodiment has an identical configuration to the configuration of the conventional LD light intensity adjustment device illustrated in FIG. 7.

In the LD light intensity adjustment device according to the first embodiment, if the amplification factor of the current amplifying circuit 209 is increased or decreased, then the monitor voltage that is the output voltage of the current amplifying circuit 209 undergoes a change. Then, depending on the switching performed by the switching unit S, the monitor voltage is compared with an output reference voltage Vs of either the reference voltage DAC 201a or the reference voltage DAC 201b of the LD drive circuit 200. The comparison result is input either to the driving current DAC 203a or the driving current DAC 203b. Thereat, by adjusting the amplification factor, the driving current DAC 203a or the driving current DAC 203b can increase or decrease the driving current to the LD 101a or the LD 101b and alter the light intensity of that LD.

Meanwhile, if there is a plurality of target light intensities due to the differences in imaging conditions in the image forming apparatus (herein, the optical scanning device), then the following operations are performed. In order to be able to obtain a plurality of target light intensities, the amplification factor is changed and the light intensity adjustment is performed. Then, based on the result of the light intensity adjustment, a plurality of digitized gain values that are based on the amplification factor used in the adjustment is stored in the nonvolatile memory 207.

In the first embodiment, the configuration is such that the light intensity adjustment is performed for each imaging condition; each adjusted gain value is independently stored in a nonvolatile memory; and a suitable gain value for each imaging condition is made selectable. Herein, predetermined imaging conditions point to the conditions under which the optical energy falling on the surface of the photosensitive member 16 undergoes a change. Thus, the imaging conditions include, for example, the speed in the sub-scanning direction of the photosensitive member 16 (the process speed), the writing density for image formation, and the number of rotations of the polygon mirror 12.

The operations of the LD light intensity adjustment device for performing light intensity adjustment are controlled by the optical writing control unit 22 or by an image forming apparatus having an optical scanning device installed therein.

The optical writing control unit 22 includes a microcomputer system having a central processing unit (CPU) 30, a read only memory (ROM) 31, and a random access memory (RAM) 32. As described later, the CPU 30 has functions of a light intensity adjustment determining unit 35, a detected-light-intensity determining unit 36, and a light intensity adjusting unit 37.

The light intensity adjustment determining unit 35 determines, based on the presence or absence of a change in the predetermined imaging conditions, whether or not it is possible to adjust the light intensity emitted from the LD 101a or the LD 101b. The detected-light-intensity determining unit 36 determines whether or not the light intensity emitted from the LD 101a or the LD 101b, which is detected by the PD 102 serving as the light intensity detecting unit, is equal to a predetermined light intensity. The light intensity adjusting unit 37 performs the following adjustment if the light intensity adjustment determining unit 35 determines that the light intensity emitted from of the LD 101a or the LD 101b needs to be adjusted. More particularly, the light intensity adjusting unit 37 causes the current amplifying circuit 209 to calculate an amplification factor from a gain value set in advance corresponding to the imaging conditions and to amplify the monitor current from the PD 102 with the amplification factor, thereby adjusting the output of the LD 101a or the LD 101b in a such way that an adjusted light intensity matches with the light intensity that is targeted by the detected-light-intensity determining unit 36.

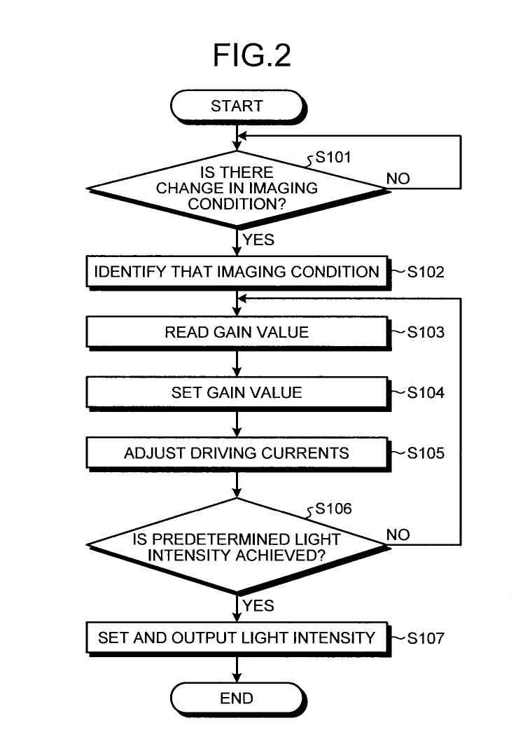

Given below is the explanation regarding the operations performed by the LD light intensity adjustment device after the light intensity adjustment is performed in the manner described above. FIG. 2 is a flowchart for explaining an example of LD light intensity adjustment performed according to the first embodiment. With reference to FIG. 2, the light intensity adjustment determining unit 35 determines the presence or absence of a change in an imaging condition (Step S101). If it is determined that there is a change in an imaging condition (Yes at Step S101), then the light intensity adjustment determining unit 35 identifies that imaging condition (Step S102). On the other hand, if it is determined that there is no change in the imaging conditions (No at Step S101); then the light intensity adjustment determining unit 35 repeats that determination.

Then, in order to relate to the imaging condition identified at Step S102, the digital gain value representing the target light intensity based on a predetermined imaging condition of the image forming apparatus is read from the nonvolatile memory 207 (Step S103). Subsequently, the gain value that is read is set in the amplification factor setting register 206, which is a temporary storage register (Step S104). Then, the light intensity adjusting unit 37 amplifies the monitor current from the PD 102 with the amplification factor set in the current amplifying circuit 209; and adjusts the driving currents of the driving current DACs 203a and 203b (Step S105).

Once the driving currents are adjusted, the LDs 101a and 101b are made to emit light as a result of adjusting the driving currents of the driving current DACs 203a and 203b. Then, the detected-light-intensity determining unit 36 determines whether or not the LDs 101a and 101b are at a predetermined light intensity (Step S106). Until the LDs 101a and 101b reach the predetermined light intensity, the detected-light-intensity determining unit 36 repeatedly performs the determination. Once the detected-light-intensity determining unit 36 determines that the LDs 101a and 101b are at a predetermined light intensity (Yes at Step S106), the adjusted light intensity is set and output (Step S107).

In this way, in order to achieve a light intensity required under a predetermined imaging condition, that is, in order to achieve a predetermined light intensity; the optical writing control unit 22 reads, from the nonvolatile memory 207, the digital gain value that represents the target light intensity based on the predetermined imaging condition of the image forming apparatus. Then, the optical writing control unit 22 sets the gain value, which has been read, in the amplification factor setting register 206, which is a temporary storage register. Then, with the amplification factor, the current amplifying circuit 209 amplifies the monitor current from the PD 102. With that, the driving currents of the driving current DACs 203a and 203b are adjusted; the LDs 101a and 101b are adjusted to a predetermined light intensity that is in accordance with the light intensity specifications set in advance; and feedback control is performed thereafter for automatically maintaining that particular light intensity.

Thus, in the LD light intensity adjustment device that is used in the optical scanning device according to the first embodiment, a gain value that represents a predetermined light intensity corresponding to an imaging condition is stored in the nonvolatile memory 207. Then, during image formation, the optical writing control unit 22 reads the gain value according to the imaging condition from the nonvolatile memory 207, and then sets that gain value in the amplification factor setting register 206 used for setting the amplification factor. With that, the current amplifying circuit 209 calculates the amplification factor from the gain value that has been set, amplifies the monitor current, and can follow the abovementioned sequence to accurately perform light intensity control (adjustment) in which the light intensity adjustment result is reflected.

Meanwhile, in the first embodiment, at the time of performing LD light intensity adjustment, the light intensity adjustment is performed based on the gain value that is adjusted and set in advance. Consequently, according to the first embodiment, it becomes possible to perform control that is not affected by the linearity error with respect to the monitor current or by the linearity error with respect to the driving current DACs used in performing the LD current control. That makes it possible to reduce the LD light intensity error. Thus, even in the case of an operation mode such as a half-speed mode of an optical scanning device in which the LD light intensity specifications are different for the same optical scanning device; it becomes possible to automatically perform light intensity control that has only a small LD light intensity error and that is equivalent to light intensity control performed using a plurality of volume resistances.

### Second Embodiment

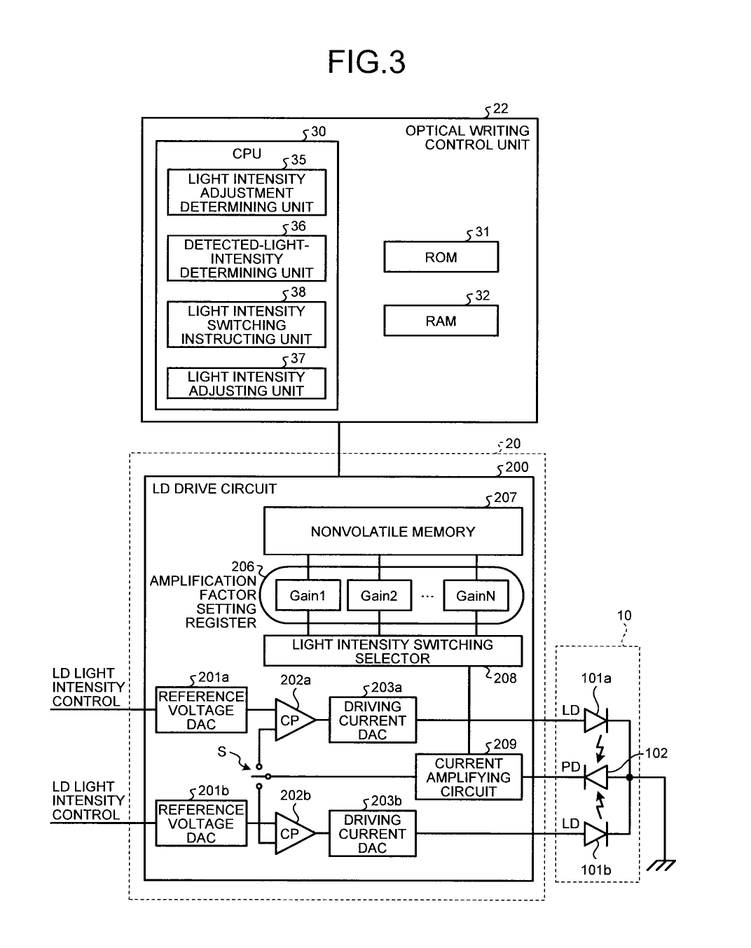

FIG. 3 is a block diagram illustrating a circuit configuration and a functional configuration of an LD light intensity adjustment device that is used in an optical scanning device according to a second embodiment of the present invention. As compared to the configuration illustrated in FIG. 1, the configuration illustrated in FIG. 3 has additional functions of a light intensity switching selector 208 and a light intensity switching instructing unit 38 that controls the light intensity switching selector 208.

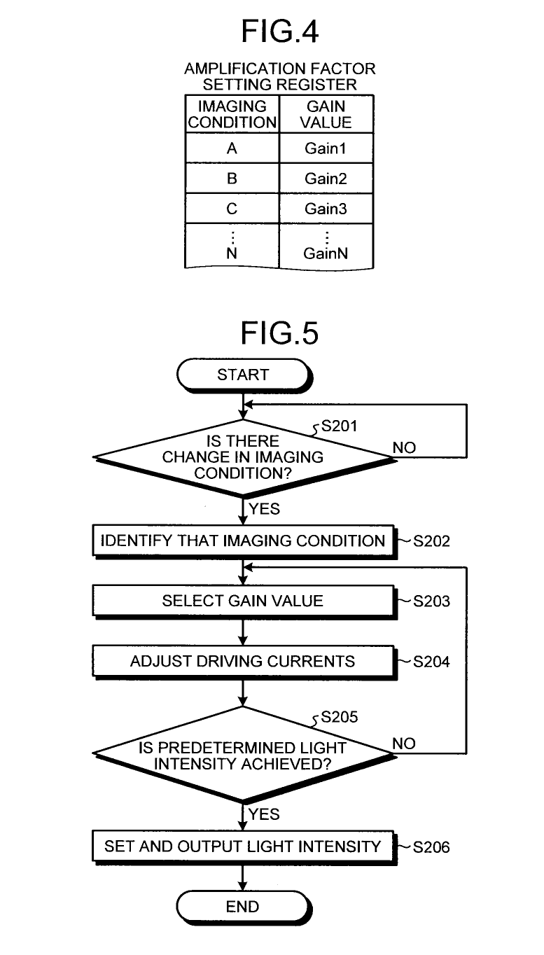

In this example, as illustrated in FIG. 4, for imaging conditions (A, B, C, . . . , N), gain values Gain1 to GainN representing amplification factors are set in a selectable manner and in the form of an amplification factor table in the amplification factor setting register 206. In FIG. 4, for example, the imaging conditions A, B, and C are respectively assumed to be the sub-scanning speed of the photosensitive member 16, the writing speed of formed images, and the number of rotations of the polygon mirror 12. Meanwhile, for a single imaging condition, it is also possible to set a plurality of gain values.

In this way, as compared to the LD light intensity adjustment device having the configuration illustrated in FIG. 1, the LD light intensity adjustment device having the configuration illustrated in FIG. 3 is different in the following manner: a plurality of the amplification factor setting registers 206, which serve as setting value memories of the current amplifying circuit 209, are disposed equal or more in number than the number of imaging conditions required by the optical scanning device. Then, a plurality of gain values obtained in advance by means of LD light intensity adjustment and in accordance with a plurality of imaging conditions are stored in the nonvolatile memory 207. In that case, before starting the image formation, the light intensity switching selector 208 operates in response to a signal from the light intensity switching instructing unit 38, and selects such a gain value from the amplification factor setting registers 206 which matches the imaging condition identified by the light intensity adjustment determining unit 35. As a result, it becomes possible to perform a predetermined light intensity control in an accurate and expeditious manner.

FIG. 5 is a flowchart for explaining an example of the LD light intensity adjustment according to the second embodiment. With reference to FIG. 5, the light intensity adjustment determining unit 35 determines the presence or absence of a change in an imaging condition (Step S201). If it is determined that there is a change in the imaging condition (Yes at Step S201), then the light intensity adjustment determining unit 35 identifies that imaging condition (Step S202). On the other hand, if it is determined that there is no change in the imaging conditions (No at Step S201); then the light intensity adjustment determining unit 35 repeats that determination.

Then, in order to relate to the imaging condition identified at Step S202, the light intensity switching instructing unit 38 performs the following operation. More particularly, of the gain values set in the amplification factor setting register 206 by controlling the light intensity switching selector 208, the light intensity switching instructing unit 38 selects the gain value corresponding to the identified imaging condition (Step S203). Then, the light intensity adjusting unit 37 causes the current amplifying circuit 209 to amplify the monitor current from the PD 102 with the selected gain value and accordingly adjusts the driving currents of the driving current DACs 203a and 203b (Step S204).

Once the driving currents are adjusted, the LDs 101a and 101b are made to emit light as a result of adjusting the driving currents of the driving current DACs 203a and 203b. Then, the detected-light-intensity determining unit 36 determines whether or not the LDs 101a and 101b are at a predetermined light intensity (Step S205). Until the LDs 101a and 101b reach the predetermined light intensity, the detected-light-intensity determining unit 36 repeatedly performs the determination. Once the detected-light-intensity determining unit 36 determines that the LDs 101a and 101b are at a predetermined light intensity (Yes at Step S205), the adjusted light intensity is set and output (Step S206).

In the LD light intensity adjustment device used in the optical scanning device according to the first embodiment, every time there is a change in an imaging condition, it is a requisite task for the optical writing control unit 22 to read a predetermined digital gain value from the nonvolatile memory 207 and to set the gain value in the amplification factor setting register 206. In contrast, in the second embodiment, the gain value for each imaging condition is set in advance in the amplification factor setting registers 206 as illustrated in FIG. 4. Thus, depending on a change in the imaging condition, one of the gain values that have been set can be selected. As a result, not only the load of the optical writing control unit 22 for performing control is not increased, but it also becomes possible to easily deal with the adjustment of LD light intensity in accordance with a new imaging condition.

Meanwhile, in the LD light intensity adjustment device described above, the two LDs 101a and 101b are arranged in an array-like manner in a single package. Alternatively, a laser diode array (LD array) can be used in which three or more LDs are arranged close to each other in an array-like manner; and the LD light intensity adjustment device can be configured to perform light intensity adjustment and light intensity control independently with respect each of the three or more LDs.

The light intensity adjusting unit 37 performs light intensity adjustment independently with respect each of a plurality of LDs. Meanwhile, if an LD array is used in which light intensity detection is performed using at least one or more PDs used in common for a plurality of LDs, it becomes possible to deal with the speeding up and high productivity of optical scanning devices. In this case, as illustrated in FIGS. 1 and 3, the switching unit S such as a switch switches between the detection outputs of laser light intensity of the PDs 102. With that, it becomes possible for a plurality of driving current DACs 203a, 203b, . . . , and so on to switch the output of a common light intensity detecting unit (PD 102) and perform the most suitable control with respect to each light emitting point.

Moreover, in the second embodiment, the number of amplification factor setting registers 206 is increased to be equal to or greater than the number of laser light sources. Besides this, the nonvolatile memory 207, the amplification factor setting registers 206, and the driving current DACs 203a and 203b serving as LD driving circuits are enclosed in a single semiconductor device. Thus, by configuring as a single semiconductor device; not only the load of the optical scanning device is not increased, but the need to provide a new nonvolatile memory is also eliminated. Moreover, it becomes possible to achieve a simple configuration without causing an increase in the manufacturing cost. Thus, in addition to achieving simplification and automation of the light intensity adjustment as well as achieving enhancement in the accuracy of the light intensity control, it becomes possible to reduce the component cost.

Furthermore, in the second embodiment, the gain values (amplification factors) that serve as light intensity adjustment values are digitized before being incorporated in a laser driving circuit. For that reason, even in the case when a plurality of different laser light intensity specifications are demanded within a single device; light intensity adjustment and light intensity control appropriate for each imaging condition can be performed in an accurate manner.

In addition, according to the second embodiment, the conventional volume resistances are digitized, and gain values for feedback control are used in place of resistance values. As a result, in comparison to the conventional LD light intensity adjustment; light intensity control in which the result of LD light intensity adjustment most suitable for a plurality of imaging conditions is reflected can be performed more accurately with a relatively simple configuration and without causing an increase in the manufacturing cost.

Meanwhile, in the second embodiment, although a current amplifying circuit is assumed to function as the amplifying unit, it is also possible to use a voltage amplifying circuit as long as predetermined gain values can be obtained.

Moreover, the optical scanning device 1 according to the embodiments that includes the laser driving device 20 and the optical writing control unit 22 is applied in an image forming apparatus such as a copying machine performing an electrophotographic process, a printer, or a facsimileing device; or is applied in a multifunction peripheral having the copying function, the printing function, and the facsimileing function. With that, the abovementioned light intensity control can be achieved. Moreover, in the embodiments, although a laser diode is used as an optical writing light source, that is not the only possible case. Alternatively, it is possible to use any light source such as an LED light source (LED stands for light emitting diode) or a liquid crystal light source that can perform optical writing on a photosensitive member.

Meanwhile, it is assumed that a computer program executed in the embodiments is stored in advance in the ROM 31. However, that is not the only possible case. Alternatively, the computer program executed in the embodiments can be recorded in the form of an installable or executable file on a computer-readable recording medium such as a compact disk read only memory (CD-ROM), a flexible disk (FD), a compact disk recordable (CD-R), or a digital versatile disk (DVD), and can be provided as a computer program product.

Still alternatively, the computer program executed in the embodiments can be saved in a downloadable manner on a computer connected to the Internet. Still alternatively, the computer program executed in the embodiments can be distributed over a network such as the Internet.

The computer program executed in the embodiments contains modules for each of the light intensity adjustment determining unit 35, the detected-light-intensity determining unit 36, the light intensity adjusting unit 37, and the light intensity switching instructing unit 38. In practice, for example, the CPU 30 (processor) reads the computer program from the recording medium mentioned above and runs it so that the computer program is loaded in a main memory device such as the RAM 32. As a result, the module for each of the light intensity adjustment determining unit 35, the detected-light-intensity determining unit 36, the light intensity adjusting unit 37, and the light intensity switching instructing unit 38 is generated in the main memory device.

According to an aspect of the present invention, during light intensity adjustment of an optical writing light source; in the case of switching to a light intensity, which is different than the light intensity with which light intensity adjustment was previously performed, depending on the imaging condition in an image forming apparatus, it becomes possible to perform a highly-accurate and error-free light intensity adjustment.

Although the invention has been described with respect to specific embodiments for a complete and clear disclosure, the appended claims are not to be thus limited but are to be construed as embodying all modifications and alternative constructions that may occur to one skilled in the art that fairly fall within the basic teaching herein set forth.

What is claimed is:

1. An optical scanning device comprising:
a light source;
a light source driving unit that drives the light source;
a light intensity detecting unit that detects light intensity emitted from the light source;
a light intensity adjustment determining unit that determines, based on the presence or absence of a change in a predetermined imaging condition, whether or not it is necessary to adjust the light intensity emitted from the light source;
a detected-light-intensity determining unit that determines whether or not the light intensity emitted from the light source detected by the light intensity detecting unit is at a predetermined light intensity; and
a light intensity adjusting unit that, when the light intensity adjustment determining unit determines that the light intensity emitted from the light source needs to be adjusted, amplifies the light intensity emitted from the light source with an amplification factor that is set according to the imaging condition to adjust a driving current of the light source driving unit and to thereby adjust the light intensity emitted from the light source, which is determined by the detected-light-intensity determining unit, to the predetermined light intensity.

2. The optical scanning device according to claim 1, further comprising an amplification factor setting/storing unit into which the light intensity adjusting unit sets, according to each of a plurality of imaging conditions, an amplification factor that is used in adjusting the light intensity of the light source.

3. The optical scanning device according to claim 1, further comprising:
an amplification factor table in which, for each of a plurality of imaging conditions, an amplification factor used in adjusting the light intensity of the light source is set in advance; and
an amplification factor switching unit that switches between the amplification factors that are set in the amplification factor table, wherein
the light intensity adjusting unit makes use of the amplification factor switching unit to select, from the amplification factor table, an amplification factor corresponding to an imaging condition identified by the light intensity adjustment determining unit and adjusts the light intensity according to the selected amplification factor.

4. The optical scanning device according to claim 3, wherein, in the amplification factor table is set a plurality of amplification factors that is equal or more in number than the number of different imaging conditions during image formation.

5. The optical scanning device according to claim 1, wherein
the light source is a semiconductor laser array in which a plurality of semiconductor laser elements are arranged in an array-like manner, and
the light intensity adjusting unit performs light intensity adjustment independently with respect to each of the plurality of semiconductor laser elements.

6. The optical scanning device according to claim 5, wherein,
in the semiconductor laser array, at least one light intensity detecting unit that is common to the plurality of semiconductor laser elements in the semiconductor laser array is embedded,
the light source driving unit includes a plurality of light source driving units corresponding to the plurality of laser diodes, and
the plurality of light source driving units operate independently based on an output of the light intensity detecting unit and drive the semiconductor laser elements.

7. A light intensity adjustment method implemented in an optical scanning device that includes a light source, a light source driving unit for driving the light source, and a light intensity detecting unit for detecting light intensity of the light source, the light intensity adjustment method comprising:
determining, based on the presence or absence of a change in a predetermined imaging condition, whether or not it is necessary to adjust the light intensity emitted from the light source;
determining whether or not the light intensity emitted from the light source detected by the light intensity detecting unit is at a predetermined light intensity; and
amplifying, when it is determined at the determining the necessity of light intensity adjustment that the light intensity emitted from the light source needs to be adjusted, the light intensity emitted from the light source with an amplification factor that is set according to the imaging condition to adjust a driving current of the light source driving unit and to thereby adjust the light intensity emitted from the light source, which is determined at the determining the light intensity, to the predetermined light intensity.

8. A computer program product comprising a non-transitory computer-readable medium including a computer program for controlling an optical scanning device that include a light source, a light source driving unit for driving the light source, and a light intensity detecting unit for detecting an amount of light of the light source, wherein the computer program causes a computer to execute:
determining, based on the presence or absence of a change in a predetermined imaging condition, whether or not it is necessary to adjust the light intensity emitted from the light source;
determining whether or not the light intensity emitted from the light source detected by the light intensity detecting unit is at a predetermined light intensity; and
amplifying, when it is determined at the determining the necessity of light intensity adjustment that the light intensity emitted from the light source needs to be adjusted, the light intensity emitted from the light source with an amplification factor that is set according to the imaging condition to adjust a driving current of the light source driving unit and to thereby adjust the light intensity emitted from the light source, which is determined at the determining the light intensity, to the predetermined light intensity.
